(19) United States
(12) Patent Application Publication
(10) Pub. No.: US 2018/0005002 A1
(43) Pub. Date: Jan. 4, 2018

(54) ULTRASONIC FINGERPRINT RECOGNITION MODULE AND MANUFACTURING METHOD THEREOF

(71) Applicant: Primax Electronics Ltd., Taipei (TW)

(72) Inventor: CHANG-MING LIN, Taipei (TW)

(21) Appl. No.: 15/598,048

(22) Filed: May 17, 2017

Related U.S. Application Data
(60) Provisional application No. 62/356,234, filed on Jun. 29, 2016.

(51) Int. Cl. G06K 9/00; H01L 21/48; H01L 23/538; H01L 23/00

(52) U.S. Cl. CPC G06K 9/0002; H01L 24/48; H01L 21/4864; H01L 23/5386; H01L 24/85; H01L 21/4853; H01L 23/5387; H01L 2224/48147; H01L 2224/48227; H01L 2224/85238

(57) ABSTRACT

An ultrasonic fingerprint recognition module and a manufacturing method thereof are provided. The ultrasonic fingerprint recognition module includes a substrate, an ultrasonic transmitter, a thin film transistor and an ultrasonic receiver. The method includes the following steps. In a step (a), the substrate, the ultrasonic transmitter, the thin film transistor and the ultrasonic receiver are provided. In a step (b), the ultrasonic transmitter is attached on a top surface of the substrate, and the ultrasonic transmitter is electrically connected with the substrate. In a step (c), the ultrasonic receiver is attached on the thin film transistor. In a step (d), the thin film transistor is attached on the ultrasonic transmitter. In a step (e), the ultrasonic receiver is electrically connected with the thin film transistor and the thin film transistor is electrically connected with the substrate through wires.

### CROSS-REFERENCE TO RELATED APPLICATION

This application claims priority to U.S. Provisional Patent Application No. 62/356,234 filed Jun. 29, 2016, the contents of which are incorporated herein by reference.

### FIELD OF THE INVENTION

The present invention relates to a fingerprint recognition module, and more particularly to an ultrasonic fingerprint recognition module.

### BACKGROUND OF THE INVENTION

With increasing development of science and technology, mobile electronic devices or notebook computers become essential devices to people. For facilitating the mobile electronic devices or the notebook computers to recognize the users' identities, the widely-used biometric recognition technologies include a face recognition technology, an iris recognition technology, a fingerprint recognition technology, and the like. Generally, a fingerprint is composed of plural raised ridges and plural recessed valleys. In addition, the fingerprint recognition technology gradually becomes one of the widely-used biometric recognition technologies.

FIG. 1 is a schematic view illustrating a conventional ultrasonic fingerprint recognition module. As shown in FIG. 1, the conventional ultrasonic fingerprint recognition module 1 comprises a flexible circuit board 10, an ultrasonic transmitter 11 and an ultrasonic receiver 12. A tail end of the flexible circuit board 10 is formed as a bent region 105. Through the bent region 105, the electric connection is established. However, the conventional ultrasonic fingerprint recognition module 1 still has some drawbacks. For example, because of the material properties of the bent region 105, the bent region 105 is elastic and the structure of the bent region 105 is unstable. In the fabricating process, it is necessary to fill a sticky bonding substance in a bent space 105a, which is defined by the bent region 105. The sticky bonding substance can assist in fixing the bent region 105. Since the process of filling the sticky bonding substance in the bent space 105a is delicate and troublesome, the labor cost is increased. After the sticky bonding substance is filled in the bent space 105a, the structural reliability of the overall ultrasonic fingerprint recognition module 1 is still unsatisfied. For example, the ultrasonic fingerprint recognition module 1 is readily suffered from warpage.

Therefore, there is a need of providing an improved ultrasonic fingerprint recognition module in order to overcome the drawbacks of the conventional technologies.

### SUMMARY OF THE INVENTION

The present invention provides an ultrasonic fingerprint recognition module. An ultrasonic transmitter, a thin film transistor and an ultrasonic receiver are directly mounted on a high density interconnect circuit board. Consequently, the overall volume is reduced. Moreover, the associated components are electrically connected with each other through wires. Consequently, the structural reliability of the overall ultrasonic fingerprint recognition module is enhanced.

In accordance with an aspect of the present invention, there is provided a method for manufacturing an ultrasonic fingerprint recognition module. The method includes the following steps. In a step (a), a substrate, an ultrasonic transmitter, a thin film transistor and an ultrasonic receiver are provided. The thin film transistor includes a first electric pad and a second electric pad. In a step (b), the ultrasonic transmitter is attached on a top surface of the substrate, and the ultrasonic transmitter is electrically connected with the substrate. In a step (c), the ultrasonic receiver is attached on the thin film transistor. In a step (d), the thin film transistor is attached on the ultrasonic transmitter. In a step (e), the ultrasonic receiver is electrically connected with the first electric pad of the thin film transistor through the first wire, and the second electric pad of the thin film transistor is electrically connected with the substrate through the second wire.

In an embodiment, the step (b) includes a sub-step (b0) of performing a plasma cleaning process to clean the top surface of the substrate.

In an embodiment, after the sub-step (b0), the step (b) further includes a sub-step (b1) of attaching the ultrasonic transmitter on the top surface of the substrate through an adhesive, and filling a conductive material into a via of the ultrasonic transmitter. Consequently, the ultrasonic transmitter and the substrate are electrically connected with each other.

In an embodiment, the adhesive is a pressure sensitive adhesive.

In an embodiment, the step (e) includes a step (e1) of performing a forward wire bonding process to sequentially weld a first end of the first wire on the ultrasonic receiver and weld a second end of the first wire on the first electric pad of the thin film transistor, and sequentially weld a first end of the second wire on the second electric pad of the thin film transistor and weld a second end of the second wire on the substrate. Alternatively, the step (e) comprises a step (e1′) of performing a reverse wire bonding process to sequentially weld a first end of the first wire on the first electric pad of the thin film transistor and weld a second end of the first wire on the ultrasonic receiver, and sequentially weld a first end of the second wire on the substrate and weld a second end of the second wire on the second electric pad of the thin film transistor.

In an embodiment, the method further includes a step (f) of attaching the substrate on a flexible circuit board after the step (e).

In an embodiment, the substrate is a high density interconnect circuit board, an electronic component is supported on the high density interconnect circuit board, and the electronic component is electrically connected with the high density interconnect circuit board.

In accordance with another aspect of the present invention, there is provided an ultrasonic fingerprint recognition module. The ultrasonic fingerprint recognition module includes a substrate, an ultrasonic transmitter, a thin film transistor, an ultrasonic receiver, a first wire and a second wire. The ultrasonic transmitter is stacked over the substrate. The thin film transistor is stacked over the ultrasonic transmitter. The thin film transistor includes a first electric pad and a second electric pad. The ultrasonic receiver is stacked over the thin film transistor. The ultrasonic receiver is electrically connected with the first electric pad of the thin film transistor through the first wire. The second electric pad of the thin film transistor is electrically connected with the substrate through the second wire.

In an embodiment, the substrate is a high density interconnect circuit board, or the substrate is a high density interconnect circuit board containing a single conductor layer.

In an embodiment, an integrated circuit is mounted on the high density interconnect circuit board, and the integrated circuit is electrically connected with the high density interconnect circuit board.

In an embodiment, a passive component is mounted on the high density interconnect circuit board, and the passive component is electrically connected with the high density interconnect circuit board.

In an embodiment, the ultrasonic transmitter and the substrate are combined together through an adhesive, and the adhesive is a pressure sensitive adhesive.

In an embodiment, the ultrasonic fingerprint recognition module further includes a flexible circuit board. The substrate is disposed on the flexible circuit board and electrically connected with the flexible circuit board.

In an embodiment, silver layers are formed on a top surface of the ultrasonic transmitter, a bottom surface of the ultrasonic transmitter and a top surface of the ultrasonic receiver.

In an embodiment, the thin film transistor includes an active zone, and the active zone includes plural sensing units that sense plural ridges and plural valleys of a fingerprint surface.

In an embodiment, the sensing units are voltage-sensing pixels, and the voltage-sensing pixels are arranged in an array.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating a conventional ultrasonic fingerprint recognition module;

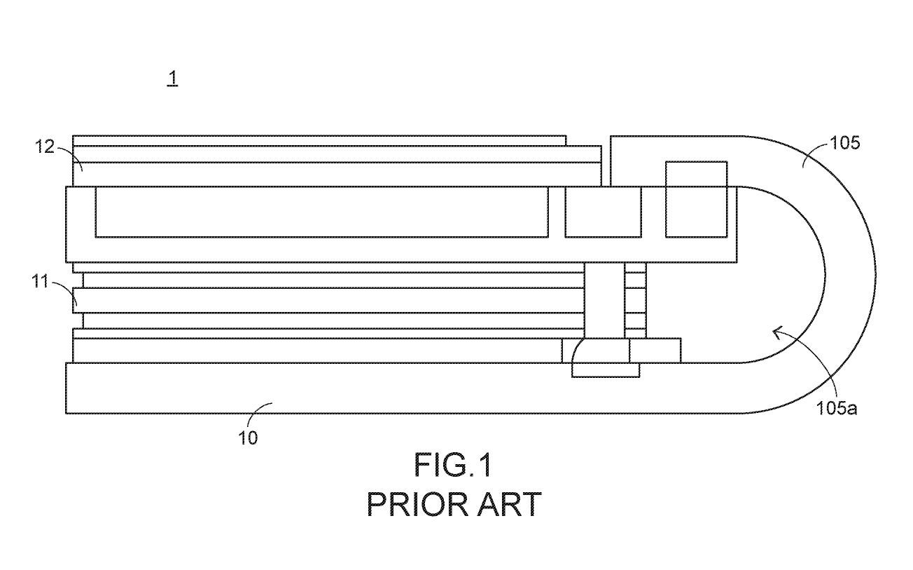

FIG. 2 is a schematic cross-sectional view illustrating an ultrasonic fingerprint recognition module according to a first embodiment of the present invention;

FIG. 3 is a schematic cross-sectional view illustrating an ultrasonic fingerprint recognition module according to a second embodiment of the present invention; and

FIG. 4A is a flowchart illustrating a method for manufacturing an ultrasonic fingerprint recognition module according to a first embodiment of the present invention.

FIG. 4B is a flowchart illustrating a method for manufacturing an ultrasonic fingerprint recognition module according to a first embodiment of the present invention.

### DETAILED DESCRIPTION OF THE PREFERRED EMBODIMENT

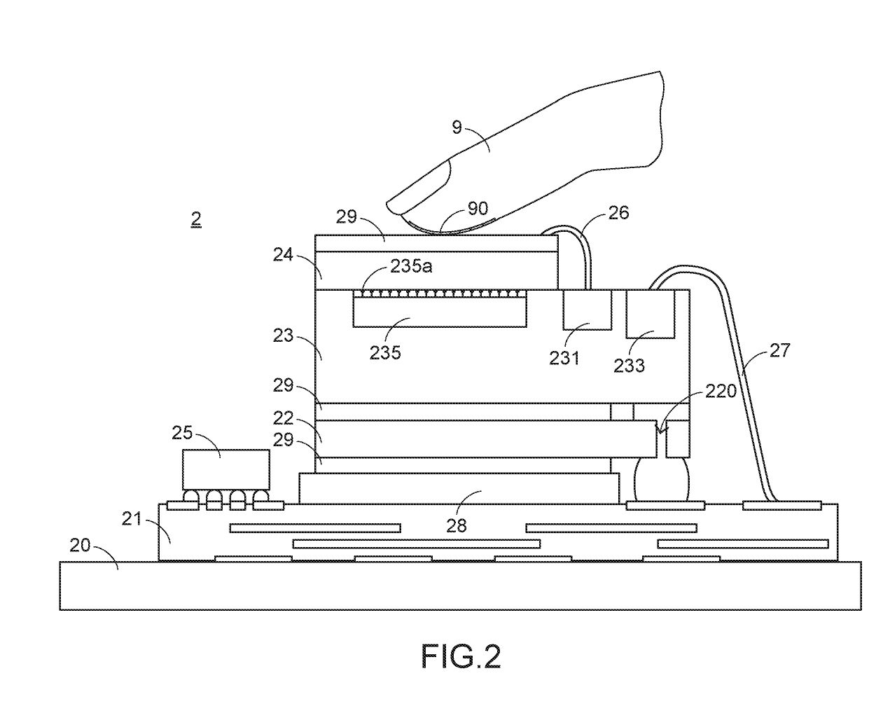

FIG. 2 is a schematic cross-sectional view illustrating an ultrasonic fingerprint recognition module according to a first embodiment of the present invention. As shown in FIG. 2, the ultrasonic fingerprint recognition module 2 comprises a substrate 21, an ultrasonic transmitter 22, a thin film transistor (TFT) 23, an ultrasonic receiver 24, a first wire 26 and a second wire 27. The above components will be described according to the sequence from bottom to top.

The substrate 21 is located at a bottom side. The ultrasonic transmitter 22 is stacked over the substrate 21. The thin film transistor 23 is stacked over the ultrasonic transmitter 22. The ultrasonic receiver 24 is stacked over the thin film transistor 23. The two ends of the first wire 26 are connected with the ultrasonic receiver 24 and a first electric pad 231 of the thin film transistor 23, respectively. Consequently, the ultrasonic receiver 24 and the thin film transistor 23 are electrically connected with each other. The two ends of the second wire 27 are connected with a second electric pad 233 of the thin film transistor 23 and the substrate 21, respectively. Consequently, the thin film transistor 23 and the substrate 21 are electrically connected with each other.

In an embodiment, the ultrasonic transmitter 22 and the ultrasonic receiver 24 of the ultrasonic fingerprint recognition module 2 are made of piezoelectric material. Consequently, the ultrasonic fingerprint recognition module 2 can generate a piezoelectric effect. Since the ultrasonic transmitter 22 is made of the piezoelectric material, the ultrasonic transmitter 22 generates a transmitted wave when the ultrasonic transmitter 22 is compressed in response to a received electric signal. When a reflected wave is received by the ultrasonic receiver 24, an electric signal is generated. In an embodiment, the substrate 21 is a high density interconnect (HDI) circuit board. Preferably, the HDI circuit board contains a single conductor layer. The HDI circuit board is thin. For example, the thickness of the HDI circuit board is 100 micrometers. Moreover, the HDI circuit board has high structural strength. Consequently, an electronic component 25 is directly supported on the HDI circuit board. Preferably, the electronic component is welded on the HDI circuit board. In such design, the electronic component 25 is very close to the ultrasonic transmitter 22, the thin film transistor 23 and the ultrasonic receiver 24. Consequently, the overall volume is reduced, flattened and minimized. An example of the electronic component 25 includes but is not limited to an integrated circuit, a microprocessor, a filter or a passive component.

Generally, the ultrasonic fingerprint recognition module 2 is installed on an electronic device (not shown). For example, the electronic device is a smart phone, a notebook computer or an electronic lock. Preferably but not exclusively, the ultrasonic fingerprint recognition module 2 further comprises a flexible circuit board 20. A top surface of the flexible circuit board 20 is connected with a bottom surface of the substrate 21. Moreover, the flexible circuit board 20 is electrically connected with the substrate 21. Consequently, when the ultrasonic fingerprint recognition module 2 is applied to the electronic device, the ultrasonic fingerprint recognition module 2 can be electrically connected with the circuit of the electronic device.

Moreover, two silver layers 29 are formed on a top surface and a bottom surface of the ultrasonic transmitter 22, respectively. Similarly, one silver layer 29 is formed on a top surface of the ultrasonic receiver 24. The silver layers 29 are used as electrodes.

Moreover, the ultrasonic transmitter 22 and the substrate 21 are combined together through an adhesive 28. For example, the adhesive 28 is a pressure sensitive adhesive (PSA) or a low temperature adhesive.

The thin film transistor 23 comprises an active zone 235. The active zone 235 comprises plural sensing units 235a. The plural sensing units 235a are used for recognizing plural ridges and plural valleys of a fingerprint surface 90 of a finger 9. Preferably, each sensing unit 235a is a voltage-sensing pixel. The plural voltage-sensing pixels 235a are arranged in an array. Moreover, the array of the voltage-sensing pixels is presented as a square array, a rectangular array or a circular array. While the fingerprint surface 90 is sensed by the ultrasonic fingerprint recognition module 2, the ultrasonic transmitter 22 generates at least one transmitted wave. When the at least one transmitted wave reaches the fingerprint surface 90, at least one reflected wave with an unique waveform is generated according to the ridges and the valleys of the fingerprint surface 90. Then, the at least one reflected wave is received by the underlying ultrasonic receiver 24. Then, the at least one reflected wave is converted into a voltage by the ultrasonic receiver 24. After the voltage from the ultrasonic receiver 24 is received by the plural sensing units 235a of the active zone 235 of the thin film transistor 23, the feature of the fingerprint surface 90 is realized.

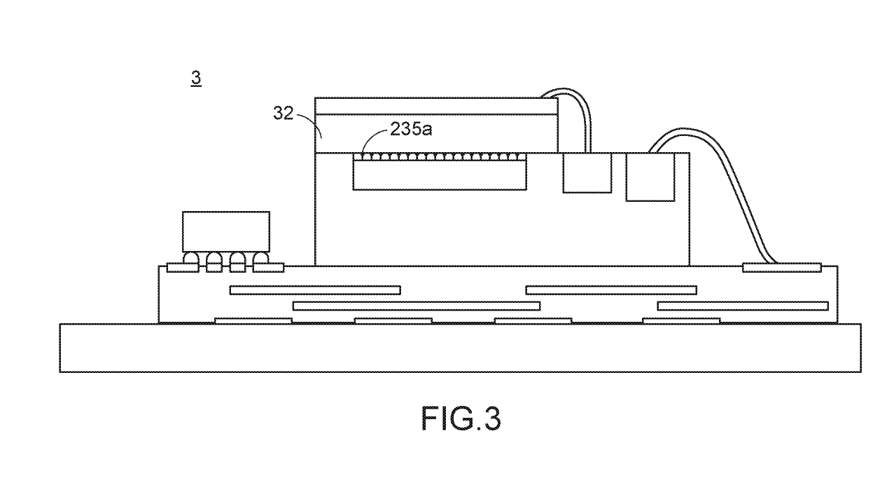

FIG. 3 is a schematic cross-sectional view illustrating an ultrasonic fingerprint recognition module according to a second embodiment of the present invention. In comparison with the first embodiment, the ultrasonic transmitter and the ultrasonic receiver of the ultrasonic fingerprint recognition module 3 of the second embodiment are formed in the same layer. That is, both of the ultrasonic transmitter and the ultrasonic receiver are included in an ultrasonic transceiver module 32. Due to this design, the overall volume of the ultrasonic fingerprint recognition module 3 is further decreased.

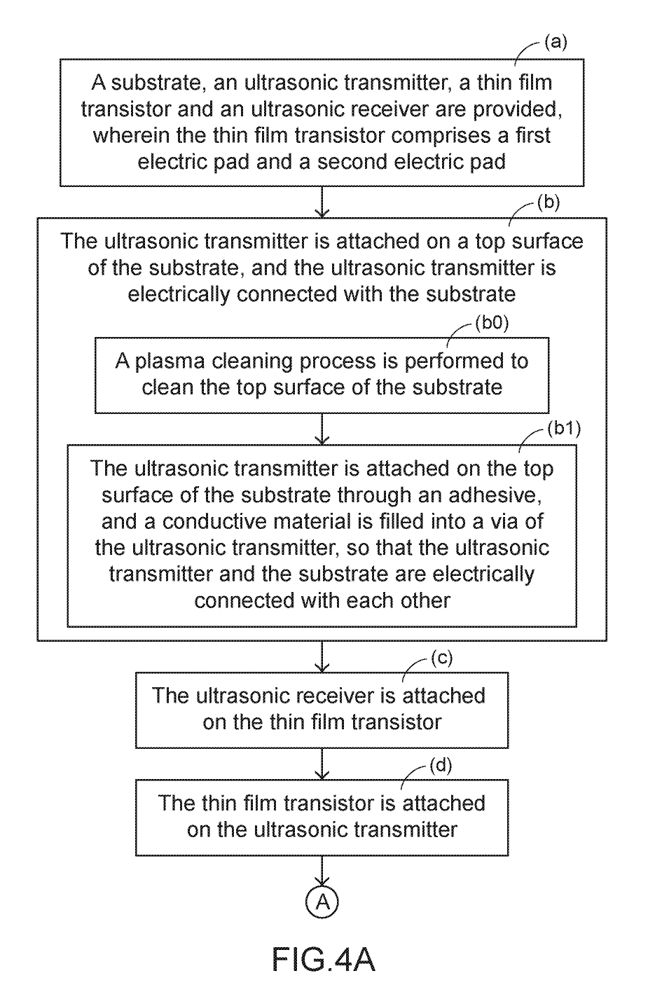

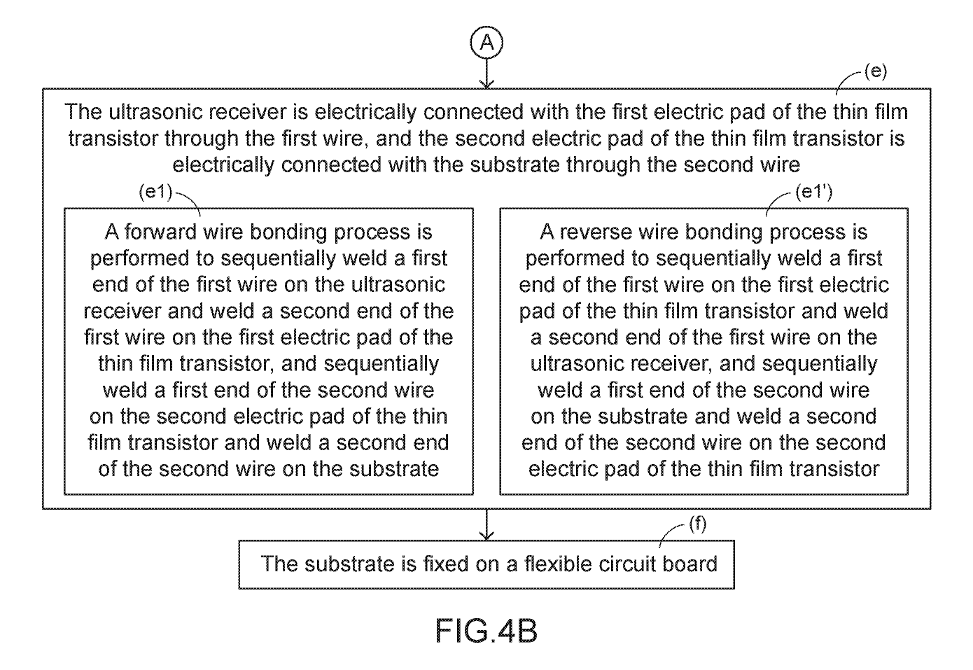

FIG. 4A and FIG. 4B are flowcharts illustrating a method for manufacturing an ultrasonic fingerprint recognition module according to a first embodiment of the present invention. Firstly, in a step (a), a substrate 21, an ultrasonic transmitter 22, a thin film transistor (TFT) 23 and an ultrasonic receiver 24 are provided. The thin film transistor 23 comprises a first electric pad 231 and a second electric pad 233. The substrate 21 is a HDI circuit board.

After the step (a), a step (b) is performed. In the step (b), the ultrasonic transmitter 22 is attached on a top surface of the substrate 21, and the ultrasonic transmitter 22 is electrically connected with the substrate 21. In an embodiment, the step (b) comprises sub-steps (b0) and (b1). In the sub-step (b0), a plasma cleaning process is performed to clean the top surface of the substrate 21. After the sub-step (b0), the sub-step (b1) is performed. In the sub-step (b1), the ultrasonic transmitter 22 is attached on the top surface of the substrate 21 through an adhesive 28. For example, the adhesive 28 is a pressure sensitive adhesive (PSA) or a low temperature adhesive. Then, a conductive material is filled into a via 220 of the ultrasonic transmitter 22. Consequently, the ultrasonic transmitter 22 and the substrate 21 are electrically connected with each other.

Then, in a step (c), the ultrasonic receiver 24 is stacked on the thin film transistor 23. As mentioned above, the ultrasonic receiver 24 is made of the piezoelectric material. Consequently, the ultrasonic receiver 24 is not very sticky. Preferably, the ultrasonic receiver 24 is produced by an ultraviolet curing process. In the ultraviolet curing process, the thin film transistor 23 is contacted with the ultrasonic receiver 24. The UV ray is irradiated to the ultrasonic receiver 24 from the side of the thin film transistor 23. Consequently, the ultrasonic receiver 24 is fixed on the thin film transistor 23. In other words, it is the reason why the ultrasonic transmitter 22, the thin film transistor 23 and the ultrasonic receiver 24 are not sequentially stacked on each other along the upward direction during the process of manufacturing the ultrasonic fingerprint recognition module 2.

Since different components are assembled in the step (b) and the step (c), the step (b) and the step (c) can be simultaneously performed or the sequences of the step (b) and the step (c) may be exchanged.

After the ultrasonic receiver 24 is stacked on the thin film transistor 23 and the ultrasonic transmitter 22 is attached on the substrate 21, a step (d) is performed. In the step (d), the thin film transistor 23 is attached on the ultrasonic transmitter 22. Preferably, before the step (d), a top surface of the ultrasonic transmitter 22 and a bottom surface of the thin film transistor 23 are cleaned by a plasma cleaning process.

After the step (d), a step (e) is performed. In the step (e), the ultrasonic receiver 24 is electrically connected with the first electric pad 231 of the thin film transistor 23 through the first wire 26, and the second electric pad 233 of the thin film transistor 23 is electrically with the substrate 21 through the second wire 27. Due to the first wire 26 and the second wire 27, the method of manufacturing the ultrasonic fingerprint recognition module 2 is simplified when compared with the conventional ultrasonic fingerprint recognition module. Moreover, the reliability of the ultrasonic fingerprint recognition module of the present invention is enhanced.

Moreover, the step (e) comprises a step (e1) or a step (e1′). The step (e1) is a forward wire bonding process. After a first end of the first wire 26 is welded on the ultrasonic receiver 24, a second end of the first wire 26 is welded on the first electric pad 231 of the thin film transistor 23. Similarly, after a first end of the second wire 27 is welded on the second electric pad 233 of the thin film transistor 23, a second end of the second wire 27 is welded on the substrate 21. The step (e1′) is a reverse wire bonding process. After a first end of the first wire 26 is welded on the first electric pad 231 of the thin film transistor 23, a second end of the first wire 26 is welded on the ultrasonic receiver 24. Similarly, after a first end of the second wire 27 is welded on the substrate 21, a second end of the second wire 27 is welded on the second electric pad 233 of the thin film transistor 23. It is noted that the number of the first electric pad 231 and the number of the second electric pad 233 are not restricted.

After the step (e), a step (f) is performed. In the step (f), the substrate 21 is attached on a flexible circuit board 20. Due to the flexible circuit board 20, the ultrasonic fingerprint recognition module 2 can be installed in an electronic device. That is, the ultrasonic fingerprint recognition module 2 is electrically connected with the electronic device through the flexible circuit board 20.

From the above descriptions, the present invention provides the ultrasonic fingerprint recognition module. The HDI circuit board, the thin film transistor and the ultrasonic receiver are electrically connected with each other through wires. Since the fabricating steps are simplified, the manufacturing method of the present invention is labor-saving and time-saving. Moreover, the overall structural strength of the ultrasonic fingerprint recognition module is increased. The ultrasonic transmitter, the thin film transistor and the ultrasonic receiver are directly mounted on the HDI circuit board. Moreover, other electronic components (e.g., the integrated circuit and the passive component) are mounted on the HDI circuit board. Consequently, the function of minimizing the volume of the ultrasonic fingerprint recognition module is achieved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing an ultrasonic fingerprint recognition module, the method comprising steps of:
(a) providing a substrate, an ultrasonic transmitter, a thin film transistor and an ultrasonic receiver, wherein the thin film transistor comprises a first electric pad and a second electric pad;
(b) attaching the ultrasonic transmitter on a top surface of the substrate and electrically connecting the ultrasonic transmitter with the substrate;
(c) attaching the ultrasonic receiver on the thin film transistor;
(d) attaching the thin film transistor on the ultrasonic transmitter; and
(e) electrically connecting the ultrasonic receiver with the first electric pad of the thin film transistor through the first wire, and electrically connecting the second electric pad of the thin film transistor with the substrate through the second wire.

2. The method according to claim 1, wherein the step (b) comprises a sub-step (b0) of performing a plasma cleaning process to clean the top surface of the substrate.

3. The method according to claim 2, wherein after the sub-step (b0), the step (b) further comprises a sub-step (b1) of attaching the ultrasonic transmitter on the top surface of the substrate through an adhesive, and filling a conductive material into a via of the ultrasonic transmitter, so that the ultrasonic transmitter and the substrate are electrically connected with each other.

4. The method according to claim 3, wherein the adhesive is a pressure sensitive adhesive.

5. The method according to claim 1, wherein the step (e) comprises a step (e1) of performing a forward wire bonding process to sequentially weld a first end of the first wire on the ultrasonic receiver and weld a second end of the first wire on the first electric pad of the thin film transistor, and sequentially weld a first end of the second wire on the second electric pad of the thin film transistor and weld a second end of the second wire on the substrate; or the step (e) comprises a step (e1′) of performing a reverse wire bonding process to sequentially weld a first end of the first wire on the first electric pad of the thin film transistor and weld a second end of the first wire on the ultrasonic receiver, and sequentially weld a first end of the second wire on the substrate and weld a second end of the second wire on the second electric pad of the thin film transistor.

6. The method according to claim 1, further comprising a step (f) of attaching the substrate on a flexible circuit board after the step (e).

7. The method according to claim 1, wherein the substrate is a high density interconnect circuit board, an electronic component is supported on the high density interconnect circuit board, and the electronic component is electrically connected with the high density interconnect circuit board.

8. An ultrasonic fingerprint recognition module, comprising:
a substrate;
an ultrasonic transmitter stacked over the substrate;
a thin film transistor stacked over the ultrasonic transmitter, wherein the thin film transistor comprises a first electric pad and a second electric pad;
an ultrasonic receiver stacked over the thin film transistor;
a first wire, wherein the ultrasonic receiver is electrically connected with the first electric pad of the thin film transistor through the first wire; and
a second wire, wherein the second electric pad of the thin film transistor is electrically connected with the substrate through the second wire.

9. The ultrasonic fingerprint recognition module according to claim 8, wherein the substrate is a high density interconnect circuit board; or the substrate is a high density interconnect circuit board containing a single conductor layer.

10. The ultrasonic fingerprint recognition module according to claim 9, wherein an integrated circuit is mounted on the high density interconnect circuit board, and the integrated circuit is electrically connected with the high density interconnect circuit board.

11. The ultrasonic fingerprint recognition module according to claim 9, wherein a passive component is mounted on the high density interconnect circuit board, and the passive component is electrically connected with the high density interconnect circuit board.

12. The ultrasonic fingerprint recognition module according to claim 9, wherein the ultrasonic transmitter and the substrate are combined together through an adhesive, and the adhesive is a pressure sensitive adhesive.

13. The ultrasonic fingerprint recognition module according to claim 9, further comprising a flexible circuit board, wherein the substrate is disposed on the flexible circuit board and electrically connected with the flexible circuit board.

14. The ultrasonic fingerprint recognition module according to claim 9, wherein silver layers are formed on a top surface of the ultrasonic transmitter, a bottom surface of the ultrasonic transmitter and a top surface of the ultrasonic receiver.

15. The ultrasonic fingerprint recognition module according to claim 9, wherein the thin film transistor comprises an active zone, and the active zone comprises plural sensing units that sense plural ridges and plural valleys of a fingerprint surface.

16. The ultrasonic fingerprint recognition module according to claim 15, wherein the sensing units are voltage-sensing pixels, and the voltage-sensing pixels are arranged in an array.
